(19) United States
(12) Patent Application Publication
(10) Pub. No.: US 2007/0231749 A1
(43) Pub. Date: Oct. 4, 2007

(54) Method for forming a semiconductor device

(75) Inventor: Shian-Jyh Lin, Taipei County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/493,271

(22) Filed: Jul. 25, 2006

(30) Foreign Application Priority Data
Apr. 3, 2006 (TW) TW95111777

(51) Int. Cl. G03F 7/26

(52) U.S. Cl. 430/313; 430/311

(57) ABSTRACT

A method for forming a gate structure includes providing a semiconductor substrate. A gate stack layer is formed on the semiconductor substrate. A first mask layer is formed on the gate stack layer. A second mask layer is formed on the first mask layer. A patterned photoresist is formed on the second mask layer. The first and second mask layer are etched by using the patterned photoresist as a mask, thus a patterned first mask layer and a patterned second mask layer are achieved. The patterned photoresist is removed. A lateral width of the patterned first mask layer is reduced by wet etching. The patterned second mask layer is removed, while the patterned first mask layer with a reduced lateral width is left. The gate stack layer is etched by using the patterned first mask layer with the reduced lateral width to form a gate structure.

### BACKGROUND OF THE INVENTION

1. Field of the Invention

The present invention relates in general to methods for forming a semiconductor device, and in particular to methods for shrinking the critical dimension of a gate structure or a conductive line.

2. Description of the Related Art

An integrated circuit comprises numerous electrical devices and circuits on a single substrate. Recent development of semiconductor technology has focused on increasing integration on a chip. By miniaturizing critical dimensions of elements on a chip, more devices can be integrated on the chip and the integration of the chip will be higher, that is, there will be more transistors on the chip. However, as critical dimensions are miniaturized, the difficulty in the photolithography gets increases. Specifically, it is more difficult to define critical dimensions of a gate length. When the demand for critical dimensions reaches sub-70 nm, the demand for ultraviolet light of the photolithography reaches 193 nm, down from 284 nm. Not only is the manufacturing process more difficult, but the photolithography costs are increased.

To overcome the difficulties in the photolithography technology, a plasma ashing method has been developed. U.S. Pat. No. 6,916,597 by Kamijima et al. entitled as “Method for fabricating a resist pattern, a method for patterning a thin film and a method for manufacturing a micro device”, discloses a method by using ashing method to narrow the photoresist, and then the line width of the device is defined through the narrowed photoresist. U.S. Pat. No. 6,140,164 by Zhang et al. entitled as “Method of manufacturing a semiconductor device”, discloses a method for reducing a mask layer by performing ashing to create a new, narrower, mask. There are some problems, however, with plasma ashing to narrow the photoresist. Because the photoresist is usually composed of organic material, it is difficult to precisely control the predetermined dimensions when the ashing process is performed. Therefore, a better method for reducing critical dimensions is desirable.

### BRIEF SUMMARY OF THE INVENTION

Methods for forming a semiconductor device are provided. Exemplary embodiments of a method for forming a gate structure include providing a semiconductor substrate. A gate stack layer is formed on the semiconductor substrate. A first mask layer is formed on the gate stack layer. A second mask layer is formed on the first mask layer. A patterned photoresist is formed on the second mask layer. The first and second mask layer are etched by using the patterned photoresist as a mask, thus a patterned first mask layer and a patterned second mask layer are achieved. The patterned photoresist is removed. A lateral width of the patterned first mask layer is reduced by wet etching. The patterned second mask layer is removed, while the patterned first mask layer with a reduced lateral width is left. The gate stack layer is etched by using the patterned first mask layer with the reduced lateral width to form a gate structure.

Methods for forming a semiconductor device are provided. Exemplary embodiments of a method for forming a conductive line include providing a layer of conductive material. A first mask layer, a second mask layer, and a patterned photoresist are sequentially formed on the layer of conductive material. The first and second mask layer are etched by using the patterned photoresist as a mask, thus a patterned first mask layer and a patterned second mask layer are achieved. The patterned photoresist is removed, while the patterned first mask layer and the patterned second mask layer are left. A lateral width of the patterned first mask layer is reduced by wet etching. The patterned second mask layer is removed, while the patterned first mask layer with a reduced lateral width is left. The layer of conductive material is etched by using the patterned first mask layer with the reduced lateral width to form a conductive line.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1a-1d shows an exemplary embodiment of a method for forming a conductive line.

FIGS. 2a-2d shows an exemplary embodiment of a method for forming a gate structure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Methods for forming a semiconductor device are provided. Exemplary embodiments of a method for forming a gate structure comprise providing a semiconductor substrate. A gate stack layer is formed on the semiconductor substrate. A first mask layer is formed on the gate stack layer. A second mask layer is formed on the first mask layer. A patterned photoresist is formed on the second mask layer. The first and second mask layer are etched by using the patterned photoresist as a mask, thus a patterned first mask layer and a patterned second mask layer are achieved. The patterned photoresist is removed. A lateral width of the patterned first mask layer is reduced by wet etching. The patterned second mask layer is removed, while the patterned first mask layer with a reduced lateral width is left. The gate stack layer is etched by using the patterned first mask layer with the reduced lateral width to form a gate structure.

Methods for forming a semiconductor device are provided. Exemplary embodiments of a method for forming a conductive line comprise providing a layer of conductive material. A first mask layer, a second mask layer, and a patterned photoresist are sequentially formed on the layer of conductive material. The first and second mask layer are etched by using the patterned photoresist as a mask, thus a patterned first mask layer and a patterned second mask layer are achieved. The patterned photoresist is removed, while the patterned first mask layer and the patterned second mask layer are left. A lateral width of the patterned first mask layer is reduced by wet etching. The patterned second mask layer is removed, while the patterned first mask layer with a reduced lateral width is left. The layer of conductive material is etched by using the patterned first mask layer with the reduced lateral width to form a conductive line.

The invention, which provides a method for reducing the critical dimension of a gate structure or a conductive line, will be described in greater detail in the following embodiments by referring to the drawing that accompany the invention. It is noted that in accompanying drawings, like and/or corresponding element are referred to by like reference numerals.

### Embodiment 1

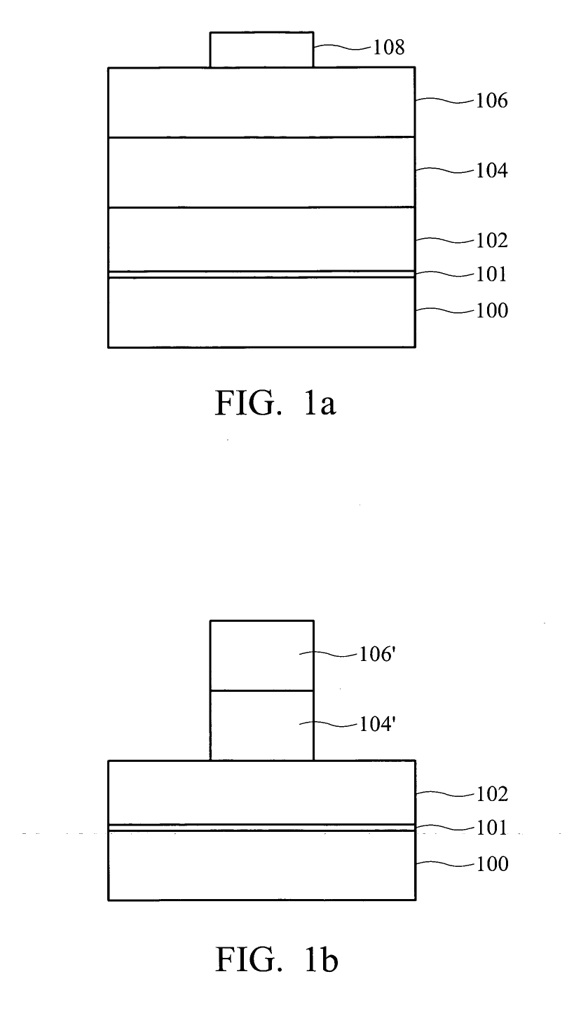

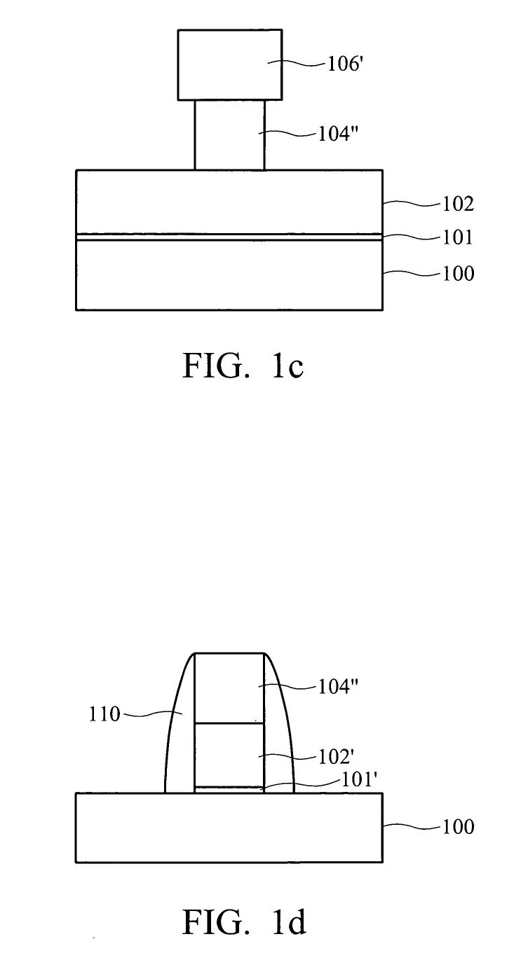

FIGS. 1a-1d are schematic views showing an exemplary embodiment of a method for forming a conductive line. Referring to FIG. 1a, a semiconductor substrate 100 with a dielectric layer 101 and a layer of conductive material 102 formed thereon is provided. The semiconductor substrate 100 may comprise Si, Ge, SiGe, GaAs, GaAlAs, InP,GaN, or a combination thereof. The dielectric layer 101 may include silicon oxide (SiO₂) or other dielectrics. The layer of conductive material 102 may include polysilicon, tungsten, molybdenum or other conductive material. A first mask layer 104 and a second mask layer 106 are then sequentially formed on the layer of conductive material 102. The first mask layer 104 may include nitride, such as silicon nitride (Si₃N₄). The second mask layer 106 with a high etch selectivity with respect to the first mask layer 104 preferably comprises carbon-doped oxide or polysilicon. A patterned photoresist 108 is formed on the second mask layer 106 to define a predetermined position of the conductive line.

Referring to FIG. 1b, the first mask layer 104 and the second mask layer 106 are etched by using the patterned photoresist 108 as a mask. The etching process may include dry etch, for example, high density plasma etch (HDPE) or reactive ion etch. (RIE). After the etching process is completed, a patterned first mask layer 104′ and the patterned second mask layer 106′ are left under the patterned photoresist 108. Finally, the patterned photoresist 108 is removed.

Referring to FIG. 1c, a wet etching process is performed to reduce a lateral width of the patterned first mask layer 104′. Thus, a patterned first mask 104″ with a reduced lateral width is obtained under the patterned second mask layer 106′. The wet etching process may use phosphoric acid (H₃PO₄) as etchant. In one example, as a first mask layer 104 is use of silicon nitride, a rate of wet etching may be about 35˜60 Å/min. During the wet etching process, the longitudinal height of the patterned first mask layer 104′ remains constant, because the patterned second mask layer 106′ located on the patterned first mask layer 104′ is capable of protecting the patterned first mask layer at its longitudinal direction against the etchant.

Referring to FIG. 1d, the patterned second mask layer 106′ is removed, while the patterned first mask layer 104″ with the reduced lateral width is left on the layer of conductive material 102. An etching process is performed to etch the layer of conductive material 102 and the dielectric layer 101 by using the patterned first mask layer 104″ with the reduced lateral width as a mask, thus a conductive line 102′ and a patterned dielectric layer 101′ is achieved. In one example, the etching process may include dry etching, such as high density plasma etching (HDPE) and reactive ion etching (RIE). Finally, insulating spacers 110 are formed on sidewalls of the conductive line 102′, the patterned dielectric layer 101′ and the patterned mask layer 104″ to complete the formation of the conductive line with a reduced critical dimension.

As noted, the difficulty in the lithography technology is overcome by forming a conductive line with a reduced critical dimension. For example, when a line width is demanded down to sub-70 nm, an ultraviolet light for defining the conductive line is also down to 193 nm. However, by using forming a conductive line with a reduced critical dimension, the lithography technology can be released from 193 nm back to 248 nm. In one example, 284 nm ultraviolet light is used for forming a phtoresist with 90 nm critical dimension, then, by controlling the etching time to reduce a lateral width of a first masking layer, a conductive line of 70 nm in width will be formed without using 193 nm ultraviolet light. In another example, a second mask layer is capable of sustaining the longitudinal height and profile of a first masking layer during a wet etching process for reducing the lateral width of the first masking layer. The unreduced longitudinal height of the first masking layer is beneficial for follow-up manufacturing processes, for example to avoid electrical shorts in the self alignment contact (SAC) process.

### Embodiment 2

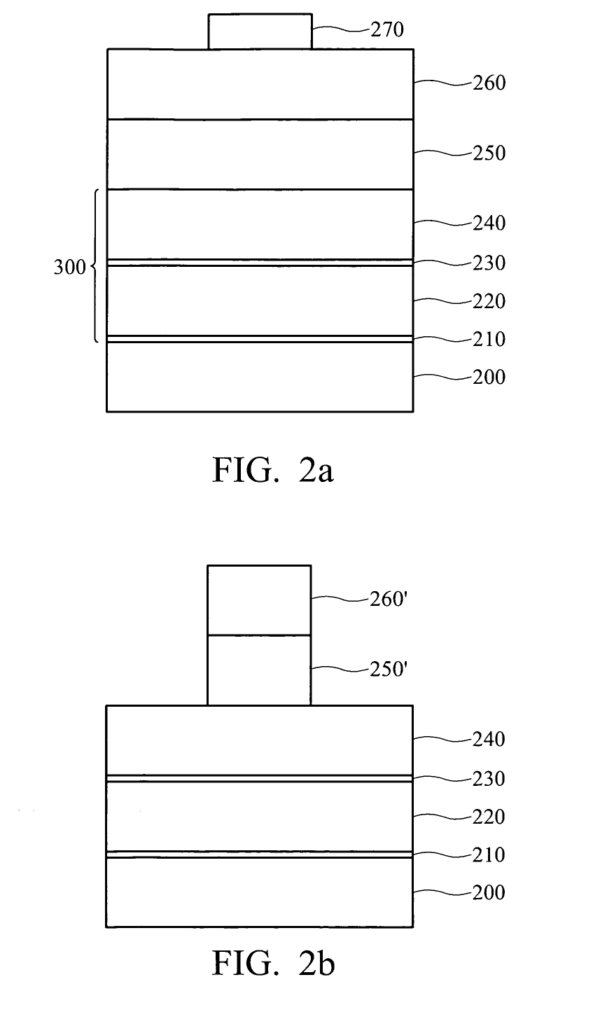

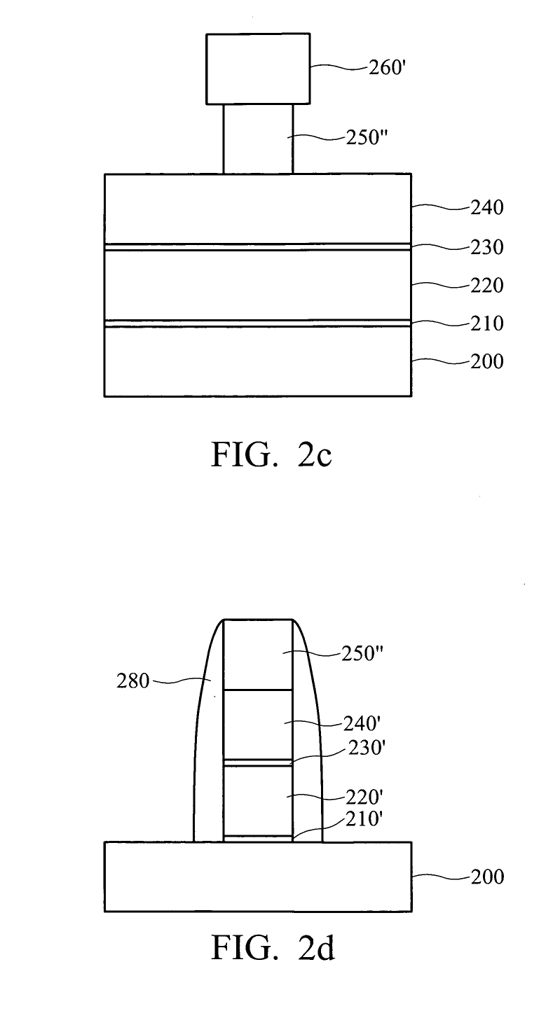

FIGS. 2a-2d are schematic views showing exemplary another embodiment of a method for forming a gate structure. Referring to FIG. 2a, a semiconductor substrate 200 with gate stack layer 300 formed thereon is provided. In one example, the gate stack layer 300 may include gate dielectric layer 210 formed on the semiconductor substrate 200, a first conductive layer 220 formed on the gate dielectric layer 210, an interface layer 230 formed on the first conductive layer 220, and a second conductive layer 240 formed on the interface layer 230. The gate dielectric layer 210 may include silicon oxide (SiO₂) or other high-k dielectrics. The first conductive layer 220 preferably comprises polysilicon, molybdenum or other conductive material. The interface layer 230, which prevents the second conductive layer 240 from penetrating the first conductive layer 220, may include tungsten nitride (WN) or titanium nitride (TiN). The second conductive layer 240 preferably comprises polysilicon, molybdenum or other conductive material. A first mask layer 250, a second mask layer 260 and a patterned photoresist 270, used to define a predetermined position for a gate structure, are sequentially formed on the conductive layer 102. In this embodiment, the semiconductor substrate 200, the first mask layer 250, and the second mask layer 260 are similar to those of the previous embodiment, detailed description thereof is omitted.

Referring to FIG. 2b, the first mask layer 250 and the second mask layer 260 are etched by using the patterned photoresist 270 as a mask. The etching process may include dry etching, for example, high density plasma etching (HDPE) and reactive ion etching (RIE). After the etching process is complete, a patterned first mask layer 250′ and a patterned second mask layer 260′ are left under the patterned photoresist 270. Finally, the patterned photoresist 270 is removed.

Referring to FIG. 2c, a wet etching process is performed to reduce a lateral width of the patterned first mask layer 250′. Therefore, a patterned first mask 250″ with a reduced lateral width is obtained under the patterned second mask layer 260′. During the wet etching process, the longitudinal height of the patterned first mask layer 250′ remains constant, because the patterned second mask layer 260′ located on the patterned first mask layer 250′ is capable of protecting the patterned first mask layer at its longitudinal direction against the etchant. The same as embodiment 1, the wet etching process may use phosphoric acid (H₃PO₄) as an etchant. When the first mask layer 250 is silicon nitride, the wet etching rate may be about 35˜60 Å/min.

Referring to FIG. 2d, the patterned second mask layer 260′ is removed, while the patterned first mask layer 250″ with the reduced lateral width is left on the gate stack layer 300. Then, an etching process is performed to etch the second conductive layer 240, the interface layer 230, the first conductive layer 220 and the gate dielectric layer 210 by using the patterned mask layer 104″ with the reduced lateral width as a mask. Thus, a patterned second conductive layer 240′, a patterned interface layer 230′, a patterned first conductive layer. 220′ and a patterned gate dielectric layer 210′ are achieved. In one example, the etching process may include dry etching, such as high density plasma etching (HDPE) and reactive ion etching (RIE). Finally, insulating spacers 280 are formed on sidewalls of the patterned second conductive layer 240′, the patterned interface layer 230′, the patterned first conductive layer 220′ and the patterned gate dielectric layer 210′ to complete formation of the gate structure with reduced critical dimension.

As noted above, the difficulty in lithography technology can be released by forming a gate structure with a reduced critical dimension.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a gate structure, comprising:
providing a semiconductor substrate;
forming a gate stack layer on the semiconductor substrate;
forming a first mask layer on the gate stack layer;
forming a second mask layer on the first mask layer;
forming a patterned photoresist on the second mask layer;
etching the first and second mask layer by using the patterned photoresist as a mask to form a patterned first mask layer and a patterned second mask layer;
removing the patterned photoresist;
reducing a lateral width of the patterned first mask layer by wet etching;
removing the patterned second mask layer, while leaving the patterned first mask layer with a reduced lateral width; and
etching the gate stack layer by using the patterned first mask layer with the reduced lateral width to form a gate structure.

2. The method for forming a gate structure as claimed in claim 1, wherein forming the gate stack layer on the semiconductor substrate comprises:
forming a gate dielectric layer on the semiconductor substrate;
forming a first conductive layer on the gate dielectric layer;
forming an interface layer on the first conductive layer; and
forming a second conductive layer on the interface layer.

3. The method for forming a gate structure as claimed in claim 2, wherein the interface layer comprises tungsten nitride.

4. The method for forming a gate structure as claimed in claim 1, wherein the first mask layer comprises silicon nitride (Si₃N₄).

5. The method for forming a gate structure as claimed in claim 4, wherein the second mask layer comprises carbon-doped oxide.

6. The method for forming a gate structure as claimed in claim 4, wherein the second mask layer comprises polysilicon.

7. The method for forming a gate structure as claimed in claim 4, wherein the wet etching comprises using phosphoric acid (H₃PO₄) as etchant.

8. The method for forming a gate structure as claimed in claim 1, wherein the wet etching is at a rate of about 35˜60 Å/min.

9. The method for forming a gate structure as claimed in claim 1, further comprising forming insulating spacers on the sidewalls of the gate structure after etching the gate stack layer.

10. The method for forming a gate structure as claimed in claim 9, wherein the insulating spacers comprise silicon nitride.

11. A method for forming a conductive line, comprising:
providing a layer of conductive material;
sequentially forming a first mask layer, a second mask layer and a patterned photoresist on the layer of conductive material;
etching the first and second mask layer by using the patterned photoresist as a mask to form a patterned first mask layer and a patterned second mask layer;
removing the patterned photoresist, while leaving the patterned first mask layer and the patterned second mask layer;
reducing a lateral width of the patterned first mask layer by wet etching;
removing the patterned second mask layer while leaving the patterned first mask layer with a reduced lateral width; and
etching the layer of conductive material by using the patterned first mask layer with the reduced lateral width to form a conductive line.

12. The method for forming a conductive line as claimed in claim 11, wherein the layer of conductive material comprises tungsten or polysilicon.

13. The method for forming a conductive line as claimed in claim 11, wherein the first mask layer comprises silicon nitride (Si₃N₄).

14. The method for forming a conductive line as claimed in claim 11, wherein the second mask layer comprises carbon-doped oxide.

15. The method for forming a conductive line as claimed in claim 11, wherein the second mask layer comprises polysilicon.

16. The method for forming a conductive line as claimed in claim 11, wherein the wet etching comprises using phosphoric acid (H₃PO₄) as etchant.

17. The method for forming a conductive line as claimed in claim 11, wherein the wet etching is at a rate of about 35˜60 Å/min.
